(19) United States
(12) Patent Application Publication
(10) Pub. No.: US 2007/0090526 A1
(43) Pub. Date: Apr. 26, 2007

(54) Semiconductor device that attains a high integration

(75) Inventor: Kazutaka Otsuki, Kawasaki (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI (JP)

(21) Appl. No.: 11/585,205

(22) Filed: Oct. 24, 2006

(30) Foreign Application Priority Data
Oct. 25, 2005 (JP) 2005-309343

(51) Int. Cl. H01L 23/48

(52) U.S. Cl. 257/734

(57) ABSTRACT

A semiconductor device includes a substrate a first wiring layer and a bonding wiring layer. On the substrate, semiconductor elements are formed. The first wiring layer is laminated on the substrate. The bonding wiring layer is bondable and laminated on the first wiring layer. The first wiring layer includes a plurality of wirings and an insulating film. The plurality of wirings is arranged in parallel along a same direction. The insulating film is filled between respective the plurality of wirings in the first wiring layer such that the insulating film supports the bonding wiring layer.

### BACKGROUND OF THE INVENTION

1. Field of the Invention The present invention relates to a semiconductor device, and more particularly relates to a semiconductor device that attains a high integration.

2. Description of the Related Art

The increase in functions in an electronic apparatus causes the increase in the number of bonding pads in a semiconductor device such as a semiconductor chip or the like. For this reason, it is firmly required to install elements under the bonding pad and effectively utilize a chip area.

On the other hand, the bonding pad formed on a surface of the semiconductor chip receives the mechanical stress that is caused by: a probe needle in a step of testing a product; and a bonding in a step of assembling the product. For this reason, when the elements are installed under the bonding pad, the characteristic of the element is required not to be varied even if the stress caused by the probe needle is received. FIG. 1A is a top view showing a schematic configuration of a conventional semiconductor device. Also, FIG. 1B is a sectional view showing the schematic configuration along the line A0-A0′ shown in FIG. 1A, when the probe needle is brought into contact with the bonding pad, in the conventional semiconductor device. As shown in FIGS. 1A and 1B, a conventional semiconductor device 101 includes: a substrate 30; a first wiring layer 6 laminated on the substrate 30; and a bondable bonding wiring layer 10 that is laminated on the first wiring layer 6. A diffusion layer 30a and the first wiring layer (1AL) 6, which are formed on the substrate 30, are electrically connected through a contact in a contact hole (CT) 7. The bonding wiring layer 10 includes a second wiring layer (2AL) 5 and a third wiring layer (3AL) 3 whose surface is actually bonded. Also, the second wiring layer 5 and the third wiring layer 3 are electrically connected through a contact in a through-hole (TH) 4. The upper portion of the bonding wiring layer 10 is covered with a cover layer 2 except the bonding pad portion, in order to protect the semiconductor device from humidity and damage. An interlayer dielectric layer is formed between the first wiring layer (1AL) 6 and the bondable bonding wiring layer 10.

However, in the conventional semiconductor device 101, as shown in FIG. 1B, there was a case that the pushed-down action of the probe needle caused cracks to be induced in the second wiring layer 5 through the third wiring layer 3 of the bonding wiring layer 10. For this reason, in particular, it was difficult to avoid the influence of the pressure on the second wiring layer 5, and it was difficult to install the elements under the bonding wiring layer 10.

In conjunction with the above description, Japanese Laid-Open Patent Application (JP-A-Heisei, 7-153922) discloses an integrated circuit. The integrated circuit includes: a substrate (201); an active element (203) formed on the surface of the substrate (201); a metal bond pad (219) installed on at least a part of the active element (203); a second metal wiring (215) which is formed between the metal bond pad (219) and the substrate (201) and covers at least a part of the active element (203); dielectric layers (214, 213 and 217) for separating the second metal layer (215) from the metal bond pad (219) and the active element (203); and conductors (251, 255 and 215) extended from the metal bond pad (219) to the active element (203).

We have now discovered that a following problem. In the conventional semiconductor device, the object is to release the mechanical stress caused by the bonding process. However, the mechanical stress on the bonding pad is generated even in the contact action with the probe needle when the product is tested. Moreover, a tip shape of the probe needle is sharper than the ball shape of a tip of a bonding wire. Thus, the concentration of the mechanical stress on the bonding pad that is caused by the probe needle is severe over that caused by the bonding wire. Then, there is a great possibility that the structural damage, such as the crack and the like, is induced in the wiring layer under the bonding pad at the time of the contact with the probe needle. For example, the first wiring layer (1AL) 6 such as an area P0 shown in FIG. 1B tends to be damaged because the tip width of the probe needle is smaller than the line width of the first wiring layer (1AL) 6. For this reason, in order to attain the higher integration of the semiconductor device by installing the elements under the bonding pad, it is especially required to develop the semiconductor device having a lamination structure which is superior in pressure resistance against the bonding pad.

### SUMMARY OF THE INVENTION

In order to achieve an aspect of the present invention, the present invention provides a semiconductor device including: a substrate on which semiconductor elements are formed; a first wiring layer which is laminated on said substrate; and a bonding wiring layer which is bondable and laminated on said first wiring layer, wherein said first wiring layer includes: a plurality of wirings which is arranged in parallel along a same direction, and an insulating film which is filled between respective said plurality of wirings in said first wiring layer such that said insulating film supports said bonding wiring layer.

In the present invention, the insulating film is formed between respective wirings of the first wiring layer to support the bonding wiring layer. Therefore, when the mechanical stress caused by a probe needle is applied to the bonding wiring layer, the influence of the mechanical stress can be reduced in the semiconductor device, especially in the first wiring layer.

According to the present invention, it is possible to provide the semiconductor device that is especially superior in the pressure resistance against the bonding pad and attains the higher integration by installing the elements under the bonding pad.

### BRIEF DESCRIPTION OF THE DRAWINGS

The above and other objects, advantages and features of the present invention will be more apparent from the following description taken in conjunction with the accompanying drawings, in which:

FIG. 1A is a top view showing a schematic configuration of a conventional semiconductor device;

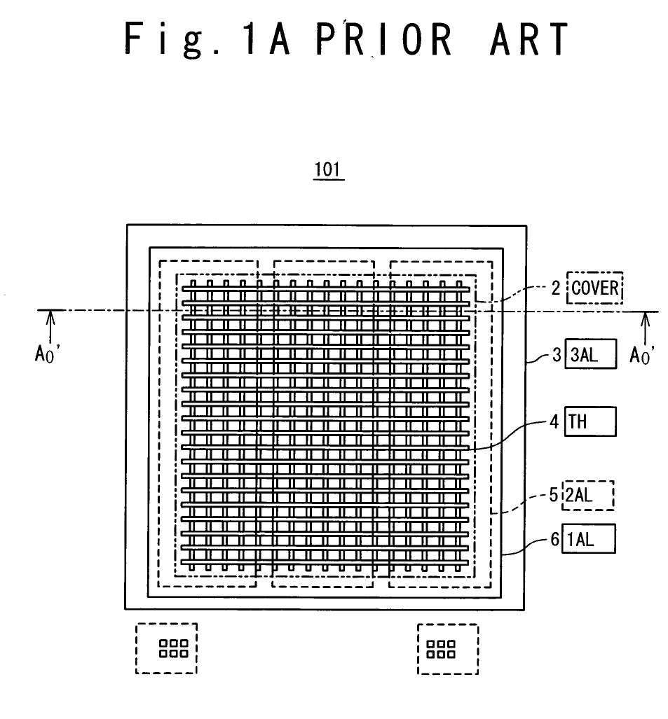

FIG. 1B is a sectional view showing the schematic configuration when the probe needle is brought into contact with the bonding pad, in the conventional semiconductor device;

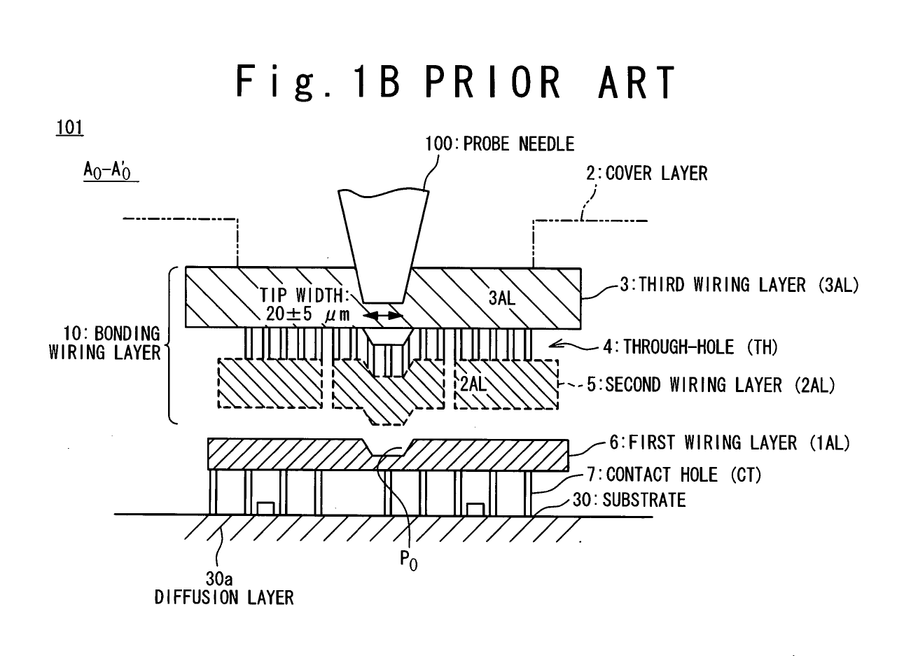

FIG. 2A is a top view showing a schematic configuration of a semiconductor device according to the first embodiment of the present invention;

FIG. 2B is a sectional view showing the schematic configuration when a probe needle is brought into contact with a bonding pad, in the semiconductor device according to the first embodiment of the present invention;

FIG. 3 is a graph showing a non-defective ratio of the semiconductor device 50 according to the first embodiment of the present invention;

FIG. 4A is a top view showing a schematic configuration of a semiconductor device according to the second embodiment of the present invention; and

FIG. 4B is a sectional view showing the schematic configuration when the probe needle is brought into contact with the bonding pad, in the semiconductor device according to the second embodiment of the present invention.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Embodiments of a semiconductor device according to the present invention will be described below with reference to the attached drawings.

The semiconductor device according to the present invention includes: a substrate where elements are formed; a bottom wiring layer having a plurality of rectangular wirings which is laminated on the substrate and installed in parallel along the same direction; and a bondable bonding wiring layer which is laminated on the bottom wiring layer. In the semiconductor device according to the present invention, in particular, a line width of the rectangular wiring in the bottom wiring layer and a width of an insulating film formed between the rectangular wirings are optimally set. Consequently, the mechanical stress caused by a probe needle which is applied to a bonding pad formed on the upper surface of the semiconductor device is supported by the insulating film.

As a result, in the semiconductor device of the present invention, the elements can be installed even immediately under the bonding pad, and the higher integration of the semiconductor device is attained.

### First Embodiment

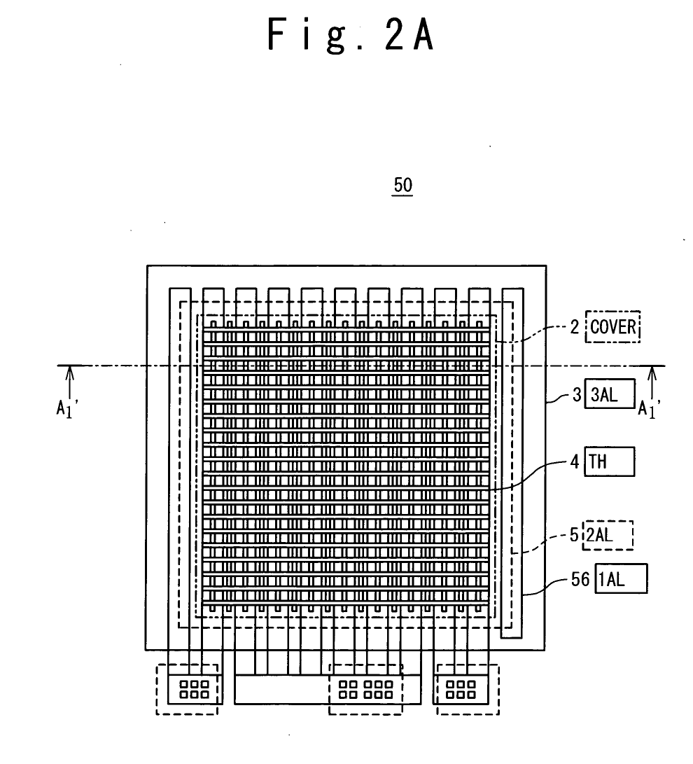

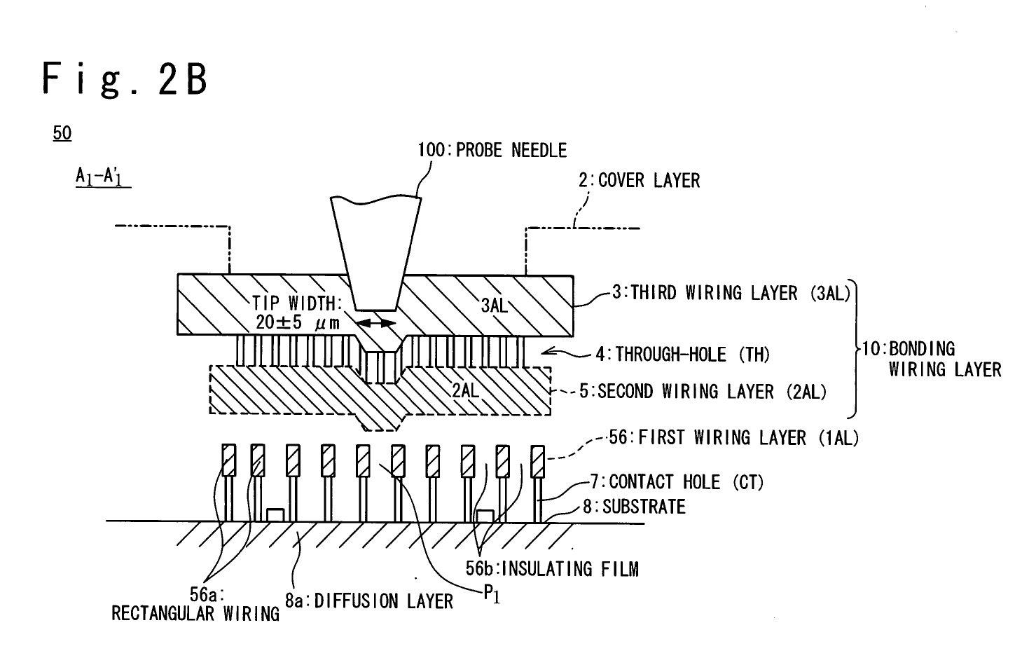

FIG. 2A is a top view showing a schematic configuration of a semiconductor device according to the first embodiment of the present invention. Also, FIG. 2B is a sectional view showing the schematic configuration along the line A1-A1′ shown in FIG. 2A, when a probe needle is brought into contact with a bonding pad, in the semiconductor device according to the first embodiment of the present invention. A semiconductor device 50 in this embodiment includes: a substrate 8; a first wiring layer (1AL) 56; and a bondable bonding wiring layer 10. On the substrate 8, semiconductor elements, for example, such as MOS transistors and the like are formed. The first wiring layer (1AL) 56 includes a plurality of rectangular wirings 56a which is laminated on the substrate 8 and arranged in parallel at a constant interval along the same direction. Each of the plurality of rectangular wirings 56a has a constant width. The bondable bonding wiring layer 10 is laminated on the first wiring layer (1AL) 56. A diffusion layer 8a and the first wiring layer (1AL) 56, which are formed on the substrate 8, are electrically connected through a contact in a contact hole (CT) 7. The bonding wiring layer 10 may have at least one or more wiring layers that are laminated on the first wiring layer (1AL) 56. The bonding wiring layer 10 in this embodiment includes: a second wiring layer (2AL) 5 laminated on the first wiring layer (1AL) 56; and a third wiring layer (3AL) 3 laminated on the second wiring layer (2AL) 5. Then, the second wiring layer (2AL) 5 and the third wiring layer (3AL) 3 are electrically connected through a contact in a through-hole (TH) 4 having a shape of a grid. In this embodiment, a cover film 2 is further installed to protect the device from humidity and external damage. The cover film 2 is installed so as to cover the upper portion except the bonding pad portion formed on the top surface of the bonding wiring layer 10. An interlayer dielectric layer is formed between the first wiring layer (1AL) 56 and the bondable bonding wiring layer 10.

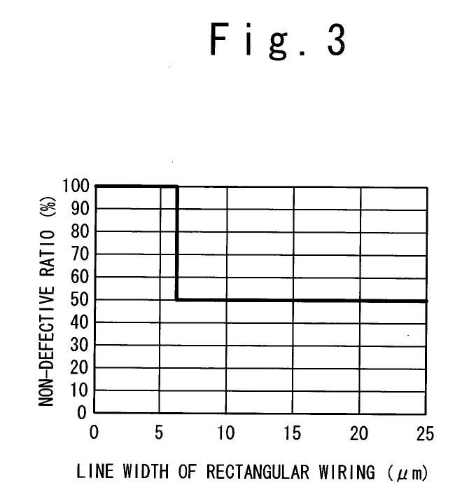

In this embodiment, an insulating film 56b made of BPSG (Boron Phosphorus Silicon Glass) film (silicon oxide film where boron and phosphorus are mixed) or silicon oxide-based film formed by HDP (High Density Plasma) is filled between the respective rectangular wirings 56a of the first wiring layer (1AL) 56. A line width of the rectangular wiring 56a of the first wiring layer (1AL) 56 and a width of the insulating film 56b filled between the rectangular wirings are set to the optimal values, mainly on the basis of the layer number of the wiring layers constituting the semiconductor device and the stress caused by the probe needle 100. FIG. 3 is a graph showing a non-defective ratio of the semiconductor device 50 according to the first embodiment of the present invention. Here, a horizontal axis shows the line width of the rectangular wiring 56a of the first wiring layer (1AL) 56. A vertical axis shows the non-defective ratio. The non-defective ratio is the probability that a crack is not induced in the second wiring layer (2AL) 5 of the semiconductor device 50 after the probe needle 100 with 15 μm in tip width is applied, when the line width of the rectangular wiring 56a has any value. The non-defective ratio is obtained by using several hundred samples for each line width.

As described in this embodiment, in the case that the bonding wiring layer 10 has the two-layer configuration, based on the result shown in FIG. 3, each line width of the rectangular wirings 56a of the first wiring layer (1AL) 56 is set to 6 μm or less, and the value of the width of the insulating film 56b filled between the respective (adjacent) rectangular wirings 56a is set to be equal to or greater than the value of the line width of each rectangular wiring.

Since the semiconductor device of this embodiment has the above-mentioned configuration, for example, as shown in FIG. 2B, even if the probe needle 100 (a tip width of a typical probe needle is 20±5 μm) is pushed down on the surface of the bonding wiring layer 10, the insulating film 56b filled between the respective rectangular wirings 56a serves as the shield and withstands the pressure generated by the pushed-down action of the probe needle 100. For this reason, it is possible to protect the structure damage caused by the mechanical stress of the probe needle 100 against the lamination layer located in and below the bonding wiring layer 10, including the second wiring layer (2AL) 5 of the bonding wiring layer 10. That is, the first wiring layer (1AL) 56 such as an area P1 shown in FIG. 2B can avoid being damaged, because the tip width of the probe needle 100 is larger than the line width of the rectangular wiring 56a and the area between the rectangular wirings 56a is filled with the insulating film 56b so that the insulating film 56b can support the bonding wiring layer 10. Consequently, in the semiconductor device 50 of the present invention, the elements such as MOS transistors and the like can be installed even immediately under the bonding pad, and the higher integration of the semiconductor device 50 is attained.

### Second Embodiment

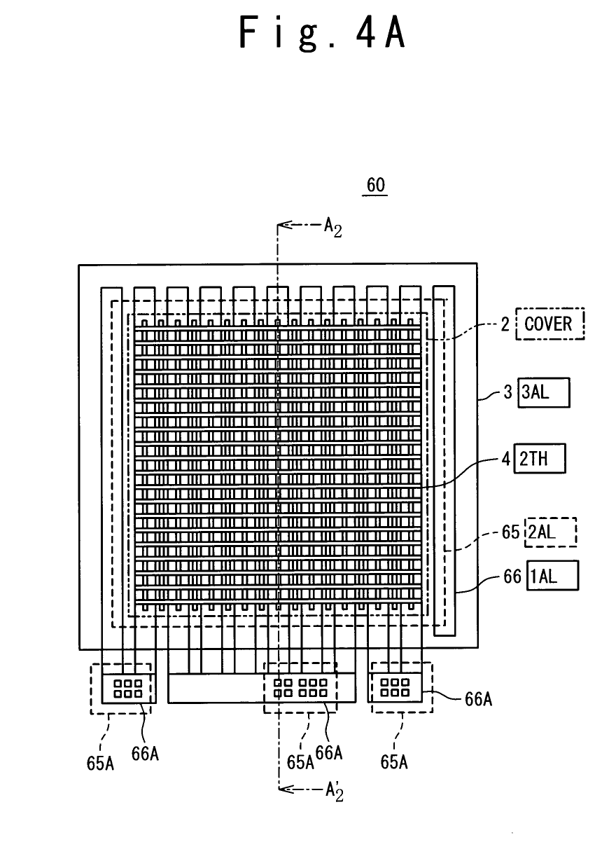

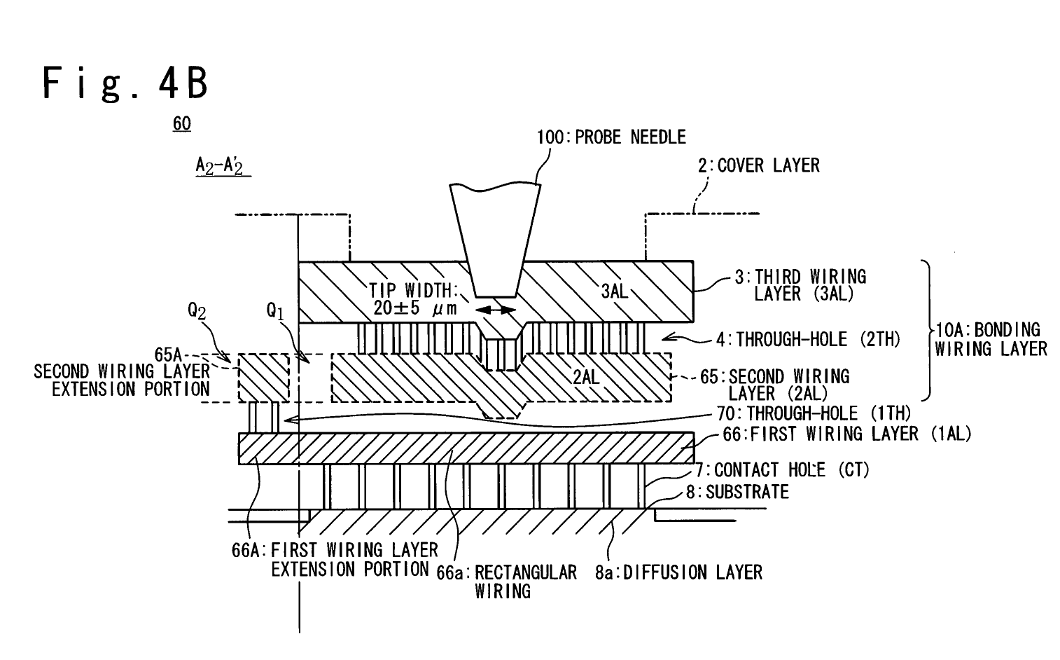

FIG. 4A is a top view showing a schematic configuration of a semiconductor device according to the second embodiment of the present invention. Also, FIG. 4B is a sectional view showing the schematic configuration along the line A2-A2′ shown in FIG. 4A, when the probe needle is brought into contact with the bonding pad, in the semiconductor device according to the second embodiment of the present invention. The basic configuration of a semiconductor device 60 of this embodiment is similar to that of the first embodiment. Here, in this embodiment, the semiconductor device 60 has the configuration that a first wiring layer (1AL) 66 and a second wiring layer (2AL) 65 constituting a bonding wiring layer 10A are electrically connected, from its functional necessity.

The semiconductor device 60 in this embodiment includes: the substrate 8; the first wiring layer (1AL) 66; and the bondable bonding wiring layer 10A. On the substrate 8, the semiconductor elements, for example, such as MOS transistors and the like are formed. The first wiring layer (1AL) 66 includes a plurality of rectangular wirings 66a which is laminated on the substrate 8 and are arranged in parallel at a constant interval along the same direction. Each of the plurality of rectangular wirings 66a has a constant width. The bondable bonding wiring layer 10A is laminated on the first wiring layer (1AL) 66. The diffusion layer 8a and the first wiring layer (1AL) 66, which are formed on the substrate 8, are electrically connected through a contact in a contact hole (CT) 7. The bonding wiring layer 10A may have at least one or more wiring layers that are laminated on the first wiring layer (1AL) 66. The bonding wiring layer 10A in this embodiment includes: the second wiring layer (2AL) 65 laminated on the first wiring layer (1AL) 66; and the third wiring layer (3AL) 3 laminated on the second wiring layer (2AL) 65. Then, the second wiring layer (2AL) 65 and the third wiring layer (3AL) 3 are electrically connected through a contact in a through-hole (2TH) 4 having a shape of a grid. In this embodiment, the first wiring layer (1AL) 66 and the second wiring layer (2AL) 65 constituting the bonding wiring layer 10A are electrically connected, especially from its functional necessity. For this reason, the first wiring layer (1AL) 66 includes a first wiring layer extension portion 66A extended outside a region where the third wiring layer 3 of the bonding wiring layer 10A is formed. Also, the second wiring layer (2AL) 65 includes a second wiring layer extension portion 65A extended outside the region where the third wiring layer 3 of the bonding wiring layer 10A is formed. Then, since the first wiring layer extension portion 66A and the second wiring layer extension portion 65A are electrically connected through a contact in a through-hole (1TH) 70, the first wiring layer (1AL) 66 and the second wiring layer (2AL) 65 constituting the bonding wiring layer 10A are electrically connected. An interlayer dielectric layer is formed between the first wiring layer (1AL) 66 and the bondable bonding wiring layer 10A.

The second wiring layer extension portion 65A may be extended to an area Q1 under the third wiring layer (3AL) 3 as shown in FIG. 4B. The second wiring layer extension portion 65A may be extended to an area Q2 farther outside the region of the third wiring layer (3AL) 3 as shown in FIG. 4B. In these cases, the first wiring layer extension portion 66A may be extended to be a suitable region where it can be connected to the second wiring layer extension portion 65A through a contact in a through-hole like the through hole 70.

In this embodiment, the cover film 2 is further installed to protect the device from the humidity and the external damage. The cover film 2 is installed so as to cover the upper portion except the bonding pad portion formed on the top surface of the bonding wiring layer 10.

In this embodiment, an insulating film 66b (not shown) made of the BPSG film (silicon oxide film where boron and phosphorus are mixed) or the silicon-oxide-based film constituted by HDP (High Density Plasma) is filled between the respective rectangular wirings 66a of the first wiring layer (1AL) 66. A line width of the rectangular wiring 66a of the first wiring layer (1AL) 66 and a width of the insulating film 66b filled between the rectangular wirings 66a are set to the optimal values, mainly on the basis of the layer number of the wiring layers constituting the semiconductor device 60 and the stress caused by the probe needle 100.

Also in this embodiment, similarly to the first embodiment, each line width of the rectangular wirings 66a of the first wiring layer (1AL) 66 is set to 6 μm or less, and the value of the width of the insulating film 66b filled between the respective rectangular wirings is set to be equal to or greater than the value of the line width of each rectangular wiring 66a.

Since the semiconductor device of this embodiment has the above-mentioned configuration, as shown in FIG. 4B, even if the probe needle is pushed down on a surface of the bonding wiring layer 10A, the insulating film 66b filled between the respective rectangular wirings 66a supports the pressure loaded by the pushed-down action of the probe needle 100. For this reason, it is possible to protect the structure damage caused by the mechanical stress of the probe needle 100 against the lamination located in and below the bonding wiring layer 10A, including the second wiring layer (2AL) 65 of the bonding wiring layer 10A. That is, the first wiring layer (1AL) 66 can avoid being damaged, because the tip width of the probe needle 100 is larger than the line width of the rectangular wiring 66a and the area between the rectangular wirings 66a is filled with the insulating film 66b so that the insulating film 66b can support the bonding wiring layer 10A. Also, a first wiring layer extension portion 66A and a second wiring layer extension portion 65A, which are extended outside the region of the bonding layer 10A, are electrically connected through the contact in the through-hole (1TH) 70, and the first wiring layer (1AL) 66 and the bonding wiring layer 10A are consequently configured so as to be electrically connected. With this electrical connection configuration, even if the probe needle 100 is pushed down on the surface of the bonding wiring layer 10A, the electrical continuity between the first wiring layer (1AL) 66 and the bonding wiring layer 10A is stably secured.

In this way, in the semiconductor device of the present invention, the electrical continuity is secured between the first wiring layer (1AL) 66 and the bonding wiring layer 10A, and the elements such as the MOS transistors and the like can be installed even immediately under the bonding pad. Thus, the higher integration of the semiconductor device is attained.

It is apparent that the present invention is not limited to the above embodiment that may be modified and changed without departing from the scope and spirit of the invention.

What is claimed is:

1. A semiconductor device comprising:
a substrate on which semiconductor elements are formed;
a first wiring layer which is laminated on said substrate; and
a bonding wiring layer which is bondable and laminated on said first wiring layer,
wherein said first wiring layer includes:
a plurality of wirings which is arranged in parallel along a same direction, and
an insulating film which is filled between respective said plurality of wirings in said first wiring layer such that said insulating film supports said bonding wiring layer.

2. The semiconductor device according to claim 1, wherein said bonding wiring layer includes:
at least two wiring layer which are laminated on said first wiring layer,
wherein a wiring portion in one of said at least two wiring layers is electrically connected to that in another of said at least two wiring layers with a first path, and
wherein said first path is formed in an area covered with a top of said at least two wiring layers.

3. The semiconductor device according to claim 2, wherein a wiring portion in said first wiring layer is electrically connected to that in one of said at least two wiring layers placed lower than said top of the at least two wiring layers with a second path,
wherein said second path is formed outside said area.

4. The semiconductor device according to claim 3, wherein said second path includes:
a first extension portion which is an extended portion of the wiring portion in said first wiring layer outside said area,
a second extension portion which is an extended portion of the wiring portion in said one of the at least two wiring layers outside said area, and
a contact portion which is formed outside said area,
wherein said first extension portion is electrically connected to said second extension portion with contact portion.

5. The semiconductor device according to claim 1, further comprising:
a cover film with which said bonding wiring layer is covered.

6. The semiconductor device according to claim 1, wherein a line width of each of said plurality of wirings is equal to or smaller than 6 μm, and
wherein a width of an region between adjacent two of said plurality of wirings, where said insulating film is filled, is equal to or larger than said line width.

7. The semiconductor device according to claim 1, wherein said insulating film is composed of at least one of BPSG (Boron Phosphorus Silicon Glass) film and silicon-oxide film formed by HDP (High Density Plasma).

8. A semiconductor device comprising,
a pad which is formed on a substrate;
a first metal wiring layer which is formed between said pad and said substrate; and
a second metal wiring layer which is formed between said first metal wiring layer and said substrate,
wherein said second metal wiring layer includes:
an insulating film which is filled among metal wirings in said second metal wiring layer such that said insulating film supports said first metal wiring layer.

9. The semiconductor device according to claim 8, wherein a wiring portion in said second metal wiring layer is electrically connected to said substrate with a first path, and
wherein said first path is formed in an area covered with said first metal wiring layers.

10. The semiconductor device according to claim 9, wherein a wiring portion in said first metal wiring layer is electrically connected to a wiring portion in said second metal wiring layer with a second path,
wherein said second path is formed outside said area.

11. The semiconductor device according to claim 10, wherein said second path includes:
a first extension portion which is an extended portion of the wiring portion in said first metal wiring layer outside said area,
a second extension portion which is an extended portion of the wiring portion in said second metal wiring layers outside said area, and
a contact portion which is formed outside said area,
wherein said first extension portion is electrically connected to said second extension portion with contact portion.

12. The semiconductor device according to claim 8, wherein a line width of each of said metal wirings is equal to or smaller than 6 μm, and
wherein a width of an region between adjacent two of said metal wirings, where said insulating film is filled, is equal to or larger than said line width.

13. The semiconductor device according to claim 8, wherein said insulating film is composed of at least one of BPSG (Boron Phosphorus Silicon Glass) film and silicon-oxide film formed by HDP (High Density Plasma).
